(19) United States
(12) Patent Application Publication
(10) Pub. No.: US 2026/0324392 A1
(43) Pub. Date: Oct. 15, 2026

(54) ENHANCED CONDUCTOR INTERCONNECTS

(71) Applicant: INTERNATIONAL BUSINESS MACHINES CORPORATION, Armonk, NY (US)

(72) Inventors: Ching-Tzu Chen, Ossining, NY (US); Oleg Gluschenkov, Tannersville, NY (US); Son Nguyen, Schenectady, NY (US); Christian Lavoie, Pleasantville, NY (US)

(21) Appl. No.: 19/178,233

(22) Filed: Apr. 14, 2025

(51) Int. Cl. H01L 23/522; H01L 21/768; H01L 23/532

(52) U.S. Cl. CPC H10W 20/42; H10W 20/034; H10W 20/039; H10W 20/067; H10W 20/425; H10W 20/4446; H10W 20/4462

(57) ABSTRACT

A semiconductor device includes a vertical interconnect having an enhanced conductor. A buffer layer is disposed between the enhanced conductor and a dielectric material. The enhanced conductor and the buffer layer include vertically disposed interfaces with surface-state conductive paths along the interfaces.

### BACKGROUND

The present invention generally relates to semiconductor devices and processing methods, and more particularly to interconnects employing conductors to provide enhanced charge transport.

Interconnects in semiconductor devices have a number of methods for formation. In one approach, the interconnects can be formed by depositing a sheet and subtractively etching the sheet to form metal lines. In another approach, a damascene method can be employed where a trench is filled with conductive material to form the interconnects. In both of these approaches, increased resistance to contacting structures, e.g., vias, contacts or other metal structures, can be present. Further, the materials employed for interconnects often include polycrystalline material which can scatter electrons resulting in resistance to electron flow.

Due to fundamental carrier-scattering physics of metals, via resistivity increases with reductions in scaling dimensions. This increases resistive loading impact on device metallization structures.

### SUMMARY

In accordance with an embodiment of the present invention, a semiconductor device includes a vertical interconnect having an enhanced conductor. A buffer layer is disposed between the enhanced conductor and a dielectric material. The enhanced conductor and the buffer layer include vertically disposed interfaces with surface-state conductive paths along the interfaces.

In accordance with an embodiment of the present invention, a semiconductor device includes an interconnect having an enhanced conductor and a buffer layer disposed between the enhanced conductor and a dielectric material. One or more insertion layers are disposed within the enhanced conductor. The one or more insertion layers and the buffer layer include interfaces with the enhanced conductor that have surface-state conductive paths along the interfaces wherein the one or more insertion layers partition the enhanced conductor into segments having dimensions of 2 nm or less.

In accordance with an embodiment of the present invention, a method of fabricating an interconnect structure includes forming a self-assembled monolayer (SAM) on a contact exposed in an opening within a dielectric layer; depositing a buffer layer on sidewalls of the opening where deposition of the buffer layer is inhibited on the contact due to the SAM layer; removing the SAM layer; depositing an enhanced conductor in the opening over the buffer layer; and forming a conductive line in direct contact with the enhanced conductor wherein the enhanced conductor and the buffer layer form interfaces having surface-state conductive paths along the interfaces.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a cross-sectional view of a semiconductor device having an enhanced conductor with a buffer layer forming an interconnect or via, in accordance with an embodiment of the present invention;

FIG. 2 shows a cross-sectional view of a semiconductor device having an enhanced conductor with a buffer layer and insertion layers segmenting the enhanced conductor to form an interconnect or via, in accordance with an embodiment of the present invention;

FIG. 3 shows a cross-sectional view of a semiconductor device having an enhanced conductor with a buffer layer where insertion layers include a centrally disposed core layer, the enhanced conductor forming an interconnect or via, in accordance with an embodiment of the present invention;

FIG. 4 shows a cross-sectional view of a semiconductor device having an enhanced conductor with a buffer layer and having contact interfaces forming an interconnect or via, in accordance with an embodiment of the present invention;

FIG. 5 shows a cross-sectional view of a semiconductor device having an enhanced conductor with a buffer layer and having contact interfaces with lines of conductors and a centrally disposed core of the same material as the contact interfaces segmenting the enhanced conductor to form an interconnect or via, in accordance with an embodiment of the present invention;

FIG. 6 shows a cross-sectional view of a semiconductor device having an enhanced conductor with a buffer layer and having contact interfaces with insertion layers having a centrally disposed core of different material than the contact interfaces segmenting the enhanced conductor to form an interconnect or via, in accordance with an embodiment of the present invention;

FIG. 7 shows a cross-sectional view of a semiconductor device having an enhanced conductor with a buffer layer and having contact interfaces with insertion layers having a centrally disposed core of the same material as the contact interfaces and the buffer layer segmenting the enhanced conductor to form an interconnect or via, in accordance with an embodiment of the present invention;

FIG. 8 shows a cross-sectional view of a semiconductor device having a contact exposed through a dielectric layer, in accordance with an embodiment of the present invention;

FIG. 9 shows a cross-sectional view of the semiconductor device having a self-assembled monolayer (SAM) formed on the contact, in accordance with an embodiment of the present invention;

FIG. 10 shows a cross-sectional view of the semiconductor device having a buffer layer selectively deposited, in accordance with an embodiment of the present invention;

FIG. 11 shows a cross-sectional view of the semiconductor device having the SAM layer removed, in accordance with an embodiment of the present invention;

FIG. 12 shows a cross-sectional view of the semiconductor device having an enhanced conductor layer (e.g., a topological conductor or anisotropic conductor) formed, in accordance with an embodiment of the present invention;

FIG. 13 shows a cross-sectional view of the semiconductor device having the enhanced conductor layer and the buffer layer planarized to form an interconnect or via, in accordance with an embodiment of the present invention;

FIG. 14 shows a cross-sectional view of the semiconductor device having a first enhanced conductor layer formed over the buffer layer in a multilayer interconnect or via structure, in accordance with an embodiment of the present invention;

FIG. 15 shows a cross-sectional view of the semiconductor device having a conductor line which segments the enhanced conductor formed over the enhanced conductor layer in the multilayer interconnect or via structure, in accordance with an embodiment of the present invention;

FIG. 16 shows a cross-sectional view of the semiconductor device having the conductor line etched to expose the contact, in accordance with an embodiment of the present invention;

FIG. 17 shows a cross-sectional view of the semiconductor device having another enhanced conductor layer formed, in accordance with an embodiment of the present invention; and

FIG. 18 shows a cross-sectional view of the semiconductor device planarized to form an interconnect or via, in accordance with an embodiment of the present invention.

### DETAILED DESCRIPTION

In accordance with embodiments of the present invention, devices and methods are described which include forming metal interconnects with topological conductors to improve electric current flow. In back end of the line (BEOL) structures, a damascene metal via (e.g., vertical interconnect access) connects a contact with a metal line. The via can be called, e.g., V0 or VA. The via can use a liner-less tungsten (W) conductor which acts as a bulk-transport metal. A target resistivity of the via filled with W can be ~30 mW-cm at a 10 nm critical dimension (CD). The actual W via resistivity can be significantly higher, however (~130 mW-cm). Due to fundamental carrier-scattering physics of metals, the via resistivity (W) increases with smaller dimensions.

In an embodiment, topological conductors, such as, e.g., topological semimetals (TSM), can be employed for interconnects in a semiconductor device. Topological conductors exhibit decreasing resistivity with reduced feature size down to less than about 2 nm. Topological conductors employ surface-state dominated transport and can improve charge flow, especially in the nm range. In an embodiment, a highly textured TSM can be employed as an interconnect conductor to reduce resistivity as compared to conventional via structures. In another embodiment. a buffer layer can also be employed as a liner-barrier-templating layer. Other embodiments can employ quasi-2D materials, such as, e.g., graphene, transition metal dichalcogenides (TMD), etc., as a trench or hole liner to promote textured growth of the TSM. In still other embodiments, a via hole can be filled with a TSM/metal/TSM multilayer to increase surface transport and further reduce resistance in the interconnect. A thin metal layer can be provided at interfaces with adjacent conductive structures, e.g., at a top (between a via (e.g., VA) and a metal line (e.g., M1) or at a bottom between a contact (e.g., CA) and the via (e.g., VA), or both, to reduce contact resistance contributions due to via resistance.

Topological conductors and anisotropic conductors may be referred to collectively as “enhanced conductors” or “advanced conductive materials.” These terms encompass materials that exhibit unique electronic properties that can improve charge transport in semiconductor devices. Enhanced conductors may include materials with topological surface states, directional conductivity, or other electronic characteristics that differ from conventional metallic conductors.

Surface state conduction provides charge transport for the topological and anisotropic conductors used in the interconnect structures. Enhanced conductive materials exhibit unique electronic states localized at their surfaces or interfaces. These surface states can arise from the topological properties of the bulk material's band structure or from strong spin-orbit coupling effects. The surface states in topological conductors can form a conductive channel that is protected against certain types of scattering. This protection can potentially lead to reduced resistivity, especially as the dimensions of the conductor are scaled down. In some cases, the surface states can maintain their conductive properties even in the presence of defects or impurities that would scatter electrons in conventional metals.

For anisotropic conductors, the surface states may exhibit directional conductivity, with charge carriers preferentially moving along certain crystallographic directions. This anisotropic behavior can be leveraged in interconnects by aligning the high-conductivity directions with the desired current flow path.

The buffer layers used in the interconnect structures may serve to enhance or preserve these surface conduction properties. In some embodiments, the interface between the buffer layer and the topological or anisotropic conductor can host additional conductive surface states, potentially further improving charge transport through the interconnect.

As the dimensions of the interconnect structures approach the nanoscale, the contribution of surface state conduction to the overall conductivity may become increasingly dominant. This effect can potentially lead to a reversal of the typical scaling trend where resistivity increases as dimensions decrease. Instead, for some topological and anisotropic conductors, the effective resistivity may decrease or remain stable as the interconnect dimensions are reduced below certain thresholds.

In embodiments of the present invention, a via structure can include a first conductive element and a second conductive element. The second conductive element can have a shape of a via and be disposed in direct contact with the first conductive element. The second conductive element can include a topological conductor, wherein the second conductive element includes a buffer layer wrapping around a topological conductor core. A conductive line can be formed in direct contact with the second conductive element. The second conductive element can include multilayers of a topological conductor compound and can include a non-topological metal whose interfaces orient roughly in parallel with the sidewalls of the second conductive element.

In an embodiment, the via structure includes a first conductive element, a first elemental metal cap or contact interface in direct contact with the first conductive element and including a first elemental metal. A second conductive element, in the shape of a via, is disposed in direct contact with the first elemental metal cap and includes a topological conductor. A second elemental metal cap or contact interface is in direct contact with the second conductive element. A conductive line is in direct contact with the second elemental metal cap.

In other embodiments, methods for fabricating an interconnect structure can include forming an opening in dielectric material (e.g., a low dielectric constant (LKD) layer). An exposed metal surface in the opening, such as a surface of a contact, can be functionalized with a self-assembled monolayer (SAM) to inhibit buffer layer growth (e.g., a TMD buffer layer to be formed). A selective deposition of a conductive monolayer or bilayer of the buffer layer is performed. The SAM layer is removed by, e.g., a hydrogen plasma or wet etch using a hydro-carbon solution. A deposition of ~2 nm of topological or anisotropic conductor in performed in the opening. A directional etch is performed to expose the contact. A deposition of ≤~1 nm of ordinary metal can be performed, followed by a directional etch to open the deposition to down to the contact. Then, the opening is filled with a topological or anisotropic conductor to complete the interconnect or via. A chemical mechanical polish (CMP) can be performed to level a free surface. A metal line (e.g., M1) or other metal structure is formed on the interconnect or via by subtractive patterning or a damascene process.

The interconnect or via provides enhanced electric current flow by reducing resistivity and charge scatter to increase permeability of charge through the interconnect or via and interfaces to the interconnect or via. Embodiments of the present invention address scaling challenges in interconnect technologies. Enhanced conductors and structures are employed to counter rising resistivity trends in vias, which can significantly reduce power dissipation, especially when scaled below 10 nm CD. The present embodiments are broadly applicable to many semiconductor technologies and are particularly useful in complementary metal oxide semiconductor (CMOS) circuitries.

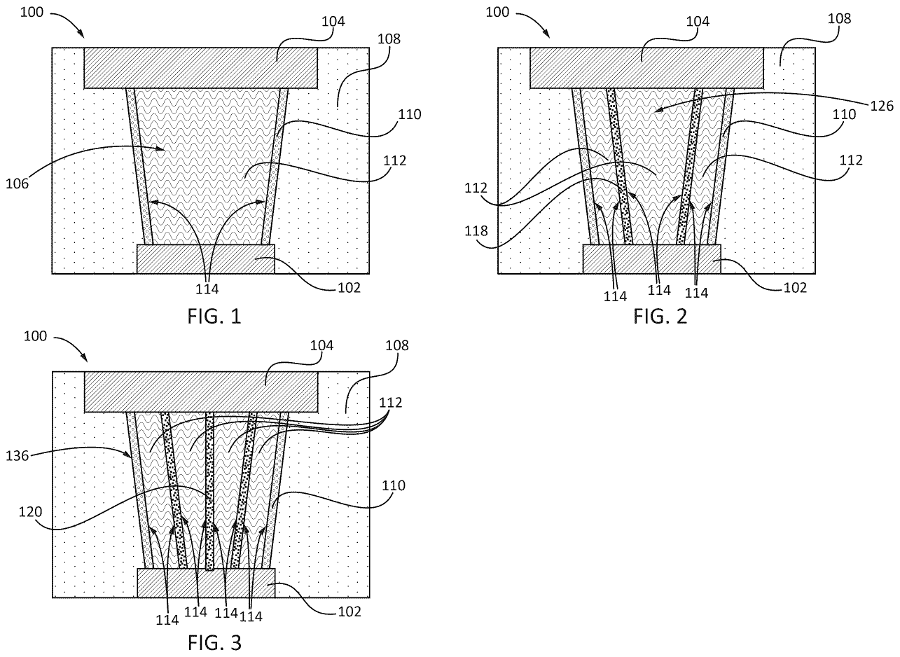

Referring now to the drawings in which like numerals represent the same or similar elements and initially to FIG. 1, devices and methods for manufacturing a semiconductor device 100 are shown in accordance with embodiments of the present invention. The semiconductor device 100 is depicted as a cross-sectional view with an area of detail between a contact 102 and a metal line 104 that are connected by a via 106 or other interconnect structure. The metal line 104 can include materials, such as W, Ru or any other suitable conductive material. The semiconductor device 100 can include any semiconductor device or chip. In particularly useful embodiments, the semiconductor device 100 includes transistors, metal interconnects and other components. These devices and components can be formed on a substrate (not shown) and connected through contacts, vias and metal lines at any level or position on or in the semiconductor device 100.

The semiconductor device 100 (or semiconductor wafer) can include a substrate (not shown) that can include a single bulk material or have multiple layers on which the semiconductor device will be fabricated. The substrate can include any suitable substrate structure or material, e.g., a bulk semiconductor, a semiconductor-on-insulator (SOI) substrate, etc., and preferably includes a monocrystalline semiconductor. In an example, the substrate can include substrate portions separated by an etch stop layer (not shown). The substrate preferably includes silicon-containing material. Illustrative examples of Si-containing materials suitable for the substrate can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

One or more layers are applied to or formed on the substrate. These layers can include front end of line (FEOL) components (e.g., source/drain regions, gate structures, etc.) in a FEOL layer and middle end of line (MOL) components (e.g., source/drain contacts, gate contacts, etc.) in the MOL layer.

A dielectric layer 108 can include any suitable material, e.g., selected from the group consisting of silicon containing materials such as SiO₂, Si₃N₄, SiOₓN_{y}, SiC, SiCO, SiCOH, SiCOₓN_{y}, SiCOₓN_{y}H, and SiCH compounds, the above-mentioned silicon containing materials with some or all of the Si replaced by Ge, carbon doped oxides, inorganic oxides, inorganic polymers, hybrid polymers, organic polymers, other carbon containing materials, organo-inorganic materials such as spin-on glasses and silsesquioxane-based materials, and diamond-like carbon (DLC), also known as amorphous hydrogenated carbon, (α-C:H). In an embodiment, the dielectric layer 108 can include low dielectric constant properties (LKD) although any suitable dielectric can be employed.

A buffer layer 110 is deposited to line the opening for the via 106. The buffer layer 110 can function as one or more of a liner, a barrier and/or a templating layer. In an embodiment, the buffer layer 110 can include one or more quasi-2D materials (e.g., layered two-dimensional materials) including graphene, multilayer graphene, mica, hexagonal boron nitride, transition metal dichalcogenides, MXenes, 2D native oxides, and 2D selenides. In an embodiment, the buffer layer 110 acts as a templating liner layer that can be formed prior to the deposition of material for a primary conductor 112 so that the primary conductor 112 growth can be facilitated along fast transport directions. Templating liner layers can include, e.g., van der Waal materials, such as, monolayer graphene, multilayer graphene, hexagonal BN, 2D transition-metal dichalcogenides (e.g., MoS₂, WSe₂, MoP₂, TaS₂, TiTe₂), GeTe, SnSe, etc. and their combinations to facilitate growth along a fast transport direction. The fast transport direction employs surface-state conduction paths 114 along interfaces between the buffer layer 110 and the primary conductor 112. In an embodiment, the buffer layer 110 can include a thickness of about 1 nm or less. The surface-state conduction paths 114 along the buffer layer 110 not only provide lower resistivity by providing pathways with little or no defects but also conducting surface states are increased.

The buffer layer 110 can be employed to provide a textured surface for the growth of the primary conductor 112, which can include a topological conductor, e.g., a topological semimetal (TSM), etc. or anisotropic conductor, e.g., PtCoO₂, etc. Testing of TSM materials has been shown to reduce resistivity with decreased conductor thickness and cross-sectional area. This is particularly pronounced at thicknesses of less than 2 nm.

In embodiments, the primary conductor 112 includes an enhanced conductor. The enhanced conductor can include but is not limited to one or more of the following topological conductors: CoSi, RhSi, CoSn, MoP, NbP, NbAs, NbSe, TiTe, TaP, TaAs, PtAl, PtGa, AlPt, GaPt, GaPd, PdGa, MoTe, MoS, WSe, WS, WTe, and more particularly, [CoSi/CoSi₂]_{N}, [CoSi/Co]_{N}, [RhSi/Rh]_{N}, [CoSn/Co]_{N}, [MoP/Mo]_{N}, [MoP₂/Mo]_{N}, [(NbP, NbAs)/Nb]_{N}, [(TaP, TaAs)/Ta]_{N}, [PtAl/Ag]_{N}, [PtGa/Ag]_{N}, [PdGa/Ag]_{N}, [MoTe₂/Mo]_{N}, [WTe₂/W]_{N} etc., or a combination or combinations thereof.

In particularly useful embodiments, the enhanced conductor of the primary conductor 112 can include but is not limited to topological conductors such as, e.g., triple point topological metal MoP, Weyl semimetal NbAs, multifold fermion semimetals CoSi and PdGa, quasi-2D type-II Weyl semimetal MoTe₂, topological Kagome metal CoSn, Dirac semimetal Cd₃As₂, and topological nodal line semimetal TiS and ZrSiS. Other topological conductors can include multifold fermion semimetals PtAl, PtGa, RhSi, Weyl semimetals NbP, TaP, TaAs, Co₂MnGa, Type-II Weyl semimetals WTe₂, WP₂, MoP₂, Ta₃S₂, LaAlGe, PrAlGe, TaIrTe₄, topological nodal line semimetals ZrSiSe, ZrSiTe, HfSiS, PbTaSe₂, PtSn4, SrIrO₃, SrZnSb₂.

The enhanced conductor of the primary conductor 112 can include but is not limited to one or more of the following anisotropic conductors: PtCoO₂, PdCoO₂, multilayer graphene (including doped graphene), van der Waals materials, such as, e.g., Fe₃GeTe₂, TaTMTe₄, NbTMTe₄, (where TM is Ir, Rh and/or Ru), WTe₂, MoTe₂.

The primary conductor 112 can include combinations of enhanced conductors, for example, combinations of topological conductors, combinations of anisotropic conductors, or combinations of both.

Referring to FIG. 2, in another embodiment, a multilayer via 126 or interconnect is shown. The multilayer via 126 includes one or more insertion layers 118 disposed vertically through the primary conductor 112. The one or more insertion layers 118 can include a conductive material, such as any metal material, e.g., W, Cu, alloys, a transition metal dichalcogenide, a graphene layer, etc. The one or more insertion layers 118 can include conductive layers having a thickness between about 1 nm and about 2 nm. The one or more insertion layers 118 can include dielectric materials. The dielectric materials can include, e.g., silicon oxide, silicon nitride, layered 2D native oxide, etc. The one or more insertion layers 118 having an insulating material can have a thickness of between about 0.3 nm and about 1.5 nm. The one or more insertion layers 118 can include semiconducting materials, e.g., Si, Ge, SiGe, etc. The semiconductor materials of the one or more insertion layers 118 can include a thickness of between about 0.3 nm and about 1.5 nm. The one or more insertion layers 118 can segment the enhanced conductor into portions. The segments or portions of the enhanced conductor can have dimensions of 2 nm or less.

The additional layers of material provided by the one or more insertion layers 118 create additional surface-state conduction paths 114 and also segment the primary conductor 112 into smaller portions. In an embodiment, the one or more insertion layers 118 are separated into portions having a dimension of less than or equal to about 2 nm to further enhance conduction. In some embodiments, the one or more insertion layers 118 run in a same direction as sidewalls of the interconnect or via. Said differently, the one or more insertion layers 118 are substantially parallel with the sidewalls of the buffer layer 110.

Referring to FIG. 3, in another embodiment, a multilayer via 126 or interconnect is shown with a core layer 120 as one of the one or more insertion layers 118 for a multilayer via 136. The core layer 120 can be the same as the one or more insertion layers 118 but is centrally disposed within the primary conductor 112. The core layer 120 can include any of the materials described for the one or more insertion layers 118. The material of the one or more insertion layers 118 can also be different than that of the core layer 120. The core layer 120 provides additional surface-state conduction paths 114 and also segments the primary conductor 112 into smaller portions. In an embodiment, the one or more insertion layers 118 and the core layer 120 separate the primary conductor 112 into smaller portions having a dimension of less than or equal to about 2 nm to further enhance conduction.

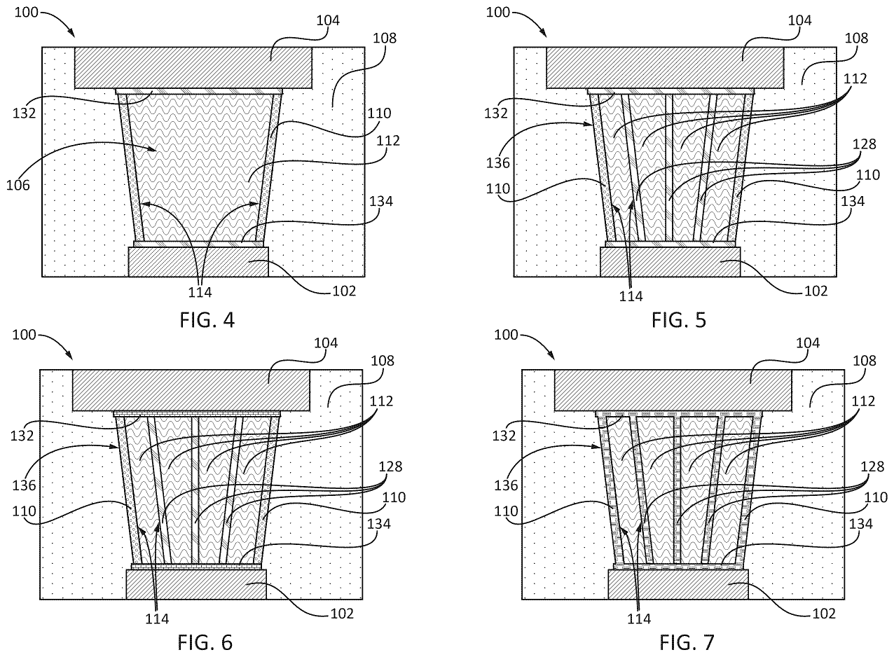

Referring to FIG. 4, in another embodiment, the via 106 or interconnect includes contact interfaces 132 and 134 or caps to improve contact resistance between the metal line 104 and the contacts 102, respectively. The via 106 includes the buffer layer 110 which can act as a barrier, liner and/or templating liner layer that can be formed prior to the deposition of primary conductor 112 so that the primary conductor 112 growth can be facilitated along fast transport directions. Templating liner layers can include, e.g., van der Waal materials, such as, monolayer graphene, multilayer graphene, hexagonal BN, 2D transition-metal dichalcogenides (e.g., MoS₂, WSe₂, MoP₂, TaS₂, TiTe₂), GeTe, SnSe, etc. and their combinations to facilitate growth along a fast transport direction. The fast transport direction employs surface-state conduction paths 114 along interfaces between the buffer layer 110 and the primary conductor 112. In an embodiment, the buffer layer 110 can include a thickness of about 1 nm or less. The buffer layer 110 can be employed to provide a textured surface for the growth of the primary conductor 112.

To further improve contact conductance, the contact interfaces 132, 134 can be formed at interfaces with the via 106. The contact interfaces 132, 134 can include highly conductive metals such as, e.g., Pt, Pd, Ag, Au, etc. The contact interfaces 132, 134 directly contact both the buffer layer 110 and the primary conductor 112.

Referring to FIG. 5, in another embodiment, the multilayer via 136 or interconnect includes contact interfaces 132 and 134 to improve contact resistance between the metal line 104 and the contact 102, respectively. The multilayer via 136 includes the buffer layer 110 which can act as a barrier, liner and/or templating liner layer that can be formed prior to the deposition of primary conductor 112 so that the primary conductor 112 growth can be facilitated along fast transport directions. Templating liner layers can include, e.g., van der Waal materials, such as, monolayer graphene, multilayer graphene, hexagonal BN, 2D transition-metal dichalcogenides and their combinations to facilitate growth along a fast transport direction.

The multilayer via 136 includes one or more insertion layers 128 disposed vertically through the primary conductor 112. The one or more insertion layers 128 can include metal, dielectric or semiconductor materials. The additional layers provided by the one or more insertion layers 128 create additional surface-state conduction paths 114 and also segment the primary conductor 112 into smaller portions. In an embodiment, the one or more insertion layers 128 separate the primary conductor 112 into portions having a dimension, e.g., of less than or equal to about 2 nm to further enhance conduction.

The surface-state conduction paths 114 along interfaces between the buffer layer 110 and the primary conductor 112 and the one or more insertion layers 128 and the primary conductor 112 improve conduction in a vertical direction between the metal lines 104 and the contact 102. In an embodiment, the buffer layer 110 can include a thickness of about 1 nm or less. The buffer layer 110 can be employed to provide a textured surface for the growth of the primary conductor 112.

The contact interfaces 132, 134 and the one or more insertion layers 128 can include a same material. In an embodiment, an ordinary metal or metal compound material suitable for semiconductor processing can be employed, e.g., W, TiN, TaN, etc., for one or more insertion layers 128. This can include a highly conductive metal, such as, e.g., Pt, Pd, Ag, Au, etc. The contact interfaces 132, 134 directly contact both the buffer layer 110 and the primary conductor 112.

Referring to FIG. 6, in another embodiment, the multilayer via 136 or interconnect includes contact interfaces 132 and 134 to improve contact resistance between the metal line 104 and the contact 102, respectively. The multilayer via 136 includes the buffer layer 110 and the one or more insertion layers 128 disposed vertically through the primary conductor 112. The one or more insertion layers 128 can include any material. The additional layers provide additional surface-state conduction paths 114 and also segment the primary conductor 112 into smaller portions. In an embodiment, the one or more insertion layers 128 are separated into portions having a dimension of less than or equal to about 2 nm to further enhance conduction.

The surface-state conduction paths 114 along interfaces between the buffer layer 110 and the primary conductor 112 and the one or more insertion layers 128 and the primary conductor 112 improve conduction in a vertical direction between the metal line 104 and the contact 102. In an embodiment, the buffer layer 110 can include a thickness of about 1 nm or less. The buffer layer 110 can be employed to provide a textured surface for the growth of the primary conductor 112.

The contact interfaces 132, 134 and the one or more insertion layers 128 can include different materials. In an embodiment, an ordinary metal material suitable for semiconductor processing can be employed for one or more insertion layers 128 while the contact interfaces 132, 134 can include a highly conductive metal, such as, e.g., Pt, Pd, Ag, Au, etc. Other materials and material combinations are also contemplated. The contact interfaces 132, 134 directly contact both the buffer layer 110 and the primary conductor 112.

Referring to FIG. 7, in another embodiment, the multilayer via 136 or interconnect includes contact interfaces 132 and 134 to improve contact resistance between the metal line 104 and the contact 102, respectively. The buffer layer 110, the one or more insertion layers 128 and contact interfaces 132 and 134 can all include a same conductive material. The material can include templating liner material, e.g., van der Waal materials, such as, monolayer graphene, multilayer graphene, hexagonal BN, 2D transition-metal dichalcogenides, an ordinary metal or metal compound material suitable for semiconductor processing, e.g., W, TiN, TaN, etc. including highly conductive metals, such as, e.g., Pt, Pd, Ag, Au, etc. The contact interfaces 132, 134 directly contact both the buffer layer 110 and the primary conductor 112.

The additional layers provide additional surface-state conduction paths 114 and also segment the primary conductor 112 into smaller portions. In an embodiment, the one or more insertion layers 128 are separated into portions having a dimension, e.g., of less than or equal to about 2 nm to further enhance conduction.

The surface-state conduction paths 114 along interfaces between the buffer layer 110 and the primary conductor 112 and the one or more insertion layers 128 and the primary conductor 112 improve conduction in a vertical direction between the metal line 104 and the contact 102. In an embodiment, the buffer layer 110 can include a thickness of about 1 nm or less. The buffer layer 110 can be employed to provide a textured surface for the growth of the primary conductor 112.

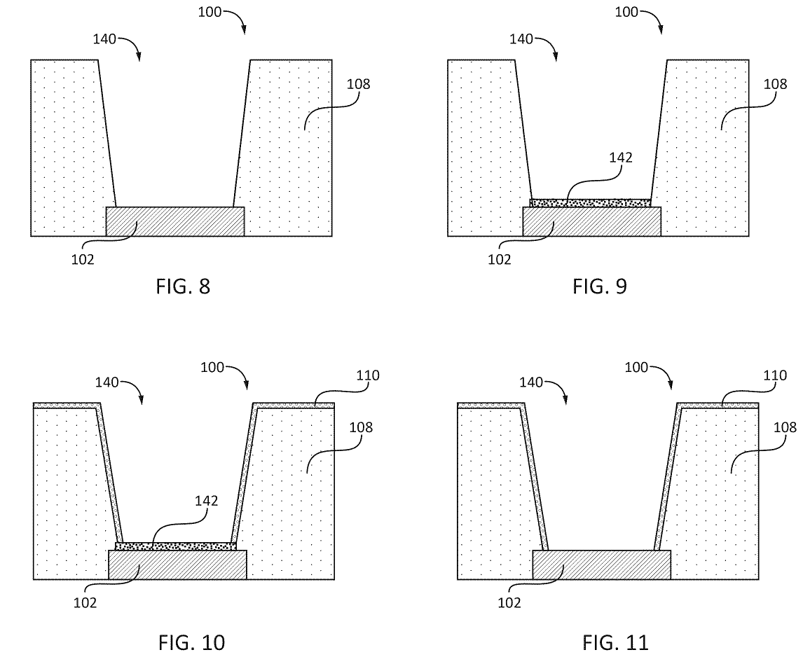

Referring to FIG. 8, methods for manufacturing the semiconductor device 100 are shown in accordance with embodiments of the present invention. The semiconductor device 100 can include any semiconductor device or chip. In particularly useful embodiments, the semiconductor device 100 includes transistors, metal interconnects and other components. These devices and components can be formed on a substrate (not shown) and connected through contacts, vias and metal lines at any level or position on or in the semiconductor device 100. The semiconductor device 100 can include one or more layers applied to or formed on the substrate. These layers can include front end of line (FEOL) components (e.g., source/drain regions, gate structures, etc.) in a FEOL layer and middle end of line (MOL) components (e.g., source/drain contacts, gate contacts, etc.) in the MOL layer. The methods described herein will focus on the formation of a via or other interconnect structure; however, embodiments of the present invention can be employed for any conductive structures where improvements in contact resistance or conductivity are beneficial,

The dielectric layer 108 can be formed and can include any suitable material, e.g., selected from the group consisting of silicon containing materials such as SiO₂, Si₃N₄, SiOₓN_{y}, SiC, SiCO, SiCOH, SiCOₓN_{y}, SiCOₓN_{y}H, and SiCH compounds, the above-mentioned silicon containing materials with some or all of the Si replaced by Ge, carbon doped oxides, inorganic oxides, inorganic polymers, hybrid polymers, organic polymers, other carbon containing materials, organo-inorganic materials such as spin-on glasses and silsesquioxane-based materials, and diamond-like carbon (DLC), also known as amorphous hydrogenated carbon, (α-C:H). In an embodiment, the dielectric layer 108 can include low dielectric constant properties (LKD) although any suitable dielectric can be employed.

The dielectric layer 108 can be deposited using chemical vapor deposition (CVD) or plasma-enhanced CVD (PECVD), although other deposition methods can be employed. While the dielectric layer 108 will illustratively be described as being part of a back end of line (BEOL) layer, embodiments of the present invention are not limited to a position within the semiconductor device 100 and can be positioned at any level/layer (e.g., FEOL, MOL, BEOL, far BEOL (FBEOL), frontside or backside of the semiconductor device 100, etc.).

The contact 102 is formed by performing a conductive fill. The conductive fill can include materials, such as, e.g., Cu, Ru, Mo, Rh, W, Ir, and alloys or combinations of these and other conductive materials. In a particularly useful embodiment, the conductive fill includes W or Cu. The conductive fill can be formed using a deposition method, such as, e.g., CVD, plasma enhanced CVD (PECVD), ALD or any other suitable deposition method.

The dielectric layer 108 is extended in depth by further deposition of material to accommodate the via 106. The dielectric layer 108 is patterned to form an opening 140 for the via 106. The dielectric layer 108 can be patterned to expose the contact 102. In an embodiment, a hard mask (not shown) may be formed by blanket depositing a layer of hard mask material, providing a patterned photoresist (not shown) on top of the layer of hard mask material, and then etching the layer of hard mask material to provide the hard mask pattern for etching the dielectric layer 108. The patterned photoresist can be produced by applying a blanket photoresist layer to the surface of the hard mask and exposing the photoresist layer to a pattern of radiation and then developing the pattern into the photoresist layer utilizing resist developer. The pattern in the photoresist layer is transferred to the hard mask by an etch process.

Referring to FIG. 9, a self-assembled molecular (SAM) layer 142 can be employed to inhibit deposition of materials employed in the formation of the buffer layer 110 (FIG. 10). The SAM layer 142 can include materials such as, e.g., vinyl pyridine, to functionalize a surface of the contact 102 to inhibit deposition of material of the buffer layer 110.

The SAM layer 142 can include organic molecules that can form a well-ordered, single-layer film through a self-assembly process. The SAM molecules may have a head group that binds to the surface of the contact 102 and a tail group that provides surface properties that inhibit deposition. The semiconductor device 100 can be immersed in a dilute solution of the SAM molecules or exposed to SAM molecules in a vapor. The SAM molecules organize on the surface of the contact 102. The SAM layer 142 modifies the surface properties altering its reactivity, wettability, or ability to nucleate material growth. This results in selective inhibition of material deposition.

Referring to FIG. 10, a selective deposition is performed to deposit the buffer layer 110. The buffer layer 110 can be deposited using a CVD or ALD deposition process. The buffer layer can include a thickness of up to about 1 nm. The selective deposition process can include the deposition of a conductive TMD monolayer or bilayer, e.g., TaS₂, NbSe₂, TiTe₂, WS₂, MoS₂, WSe₂, MoP₂, or the like. The buffer layer forms on sidewalls of the opening 140 on the surface of the dielectric layer 108 but is prevented from forming on the SAM layer 142 which prevents nucleation of the deposition materials thereon.

Referring to FIG. 11, the SAM layer 142 is removed by an etch process. In an embodiment, the SAM layer 142 is removed by a hydrogen plasma etch. In another embodiment, the SAM layer 142 can be removed by a wet etch using a hydrocarbon solution. The buffer layer 110 protects the dielectric layer 108 during the removal of the SAM layer 142.

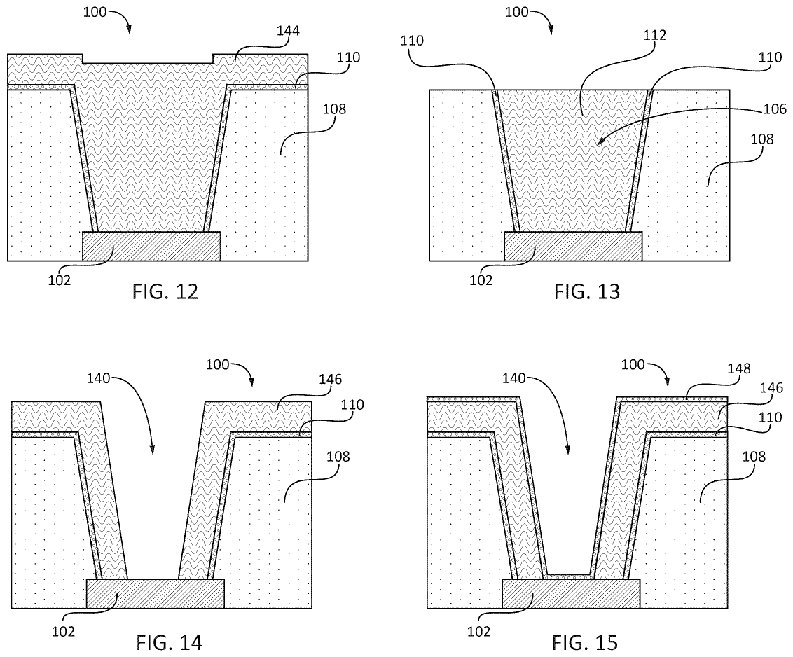

Referring to FIG. 12, the opening 140 is filled with a conductor 144. The conductor 144 includes an enhanced conductor (e.g., a topological or anisotropic conductor). The conductor 144 can include one or more of the materials described for the primary conductor 112. The conductor 144 can be deposited using CVD, ALD or any other suitable deposition process. The conductor 144 is deposited over the buffer layer 110. The buffer layer 110 provides a templating layer having rough or textures features to assist in the nucleation of the materials of the conductor 144, e.g., the topological or anisotropic conductor.

Referring to FIG. 13, a free surface of the semiconductor device 100 can be planarized using e.g., chemical mechanical polishing (CMP). The CMP process removes excess material of the conductor 144 and the buffer layer 110 down to the dielectric layer 108. This forms the primary conductor of the via 106 (see also FIG. 1). Processing continues with the formation of metal line 104 (FIG. 1) by subtractive patterning of a plate to form metal lines or by forming damascene structure metal lines.

Referring to FIG. 14, other embodiments include methods for forming multilayer vias. Beginning with the structure of FIG. 11, the opening 140 can be filled. In an embodiment, a conductor layer 146 is deposited over the buffer layer 110 to fill the opening 140. The conductor layer 146 includes an enhanced conductor, such as, e.g., a topological or anisotropic conductor. The conductor layer 146 can include one or more of the materials described for the primary conductor 112. The conductor layer 146 can be deposited using CVD, ALD or any other suitable deposition process. The buffer layer 110 provides a templating layer having rough or textures features to assist in the nucleation of the materials of the conductor layer 146, e.g., the topological or anisotropic conductor. The conductor layer 146 can include any thickness; however, a thickness of 2 nm or less is preferred. A directional etch, e.g., a reactive ion etch (RIE) is performed to etch the conductor layer 146 to expose the contact 102.

Referring to FIG. 15, a partition layer 148 is deposited over the conductor layer 146. The partition layer 148 can be deposited using CVD, ALD or any other suitable deposition process. The partition layer 148 can include any material. In some embodiments, the partition layer 148 can include a conductive layer, a dielectric or semiconductor layer. The partition layer 148 can have a thickness of about 1 nm or less. The partition layer 148 can function as a templating layer having rough or textured features to assist in the nucleation of the materials of a next conductor layer 150, e.g., a topological or anisotropic conductor. A directional etch, e.g., RIE is performed to expose the contact 102.

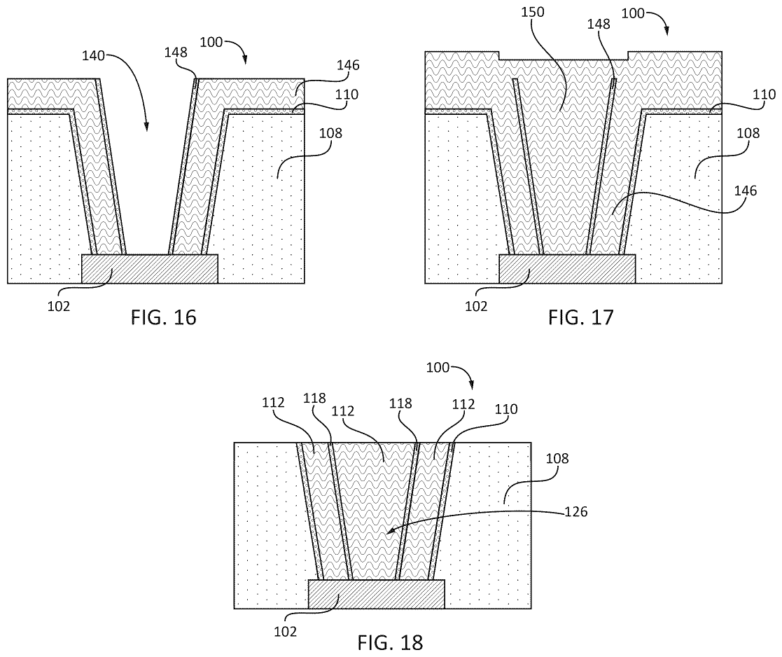

Referring to FIG. 16, a directional etch, e.g., RIE, is performed to etch the partition layer 148 to expose the conductor layer 146 and to expose the contact 102.

Referring to FIG. 17, another conductor layer 150 is deposited over the partition layer 148 and the conductor layer 146 to fill the opening 140. The conductor layer 150 includes an enhanced conductor, e.g., a topological or anisotropic conductor. The conductor layer 150 can include one or more of the materials described for the primary conductor 112. The conductor layer 150 can be deposited using CVD, ALD or any other suitable deposition process. The partition layer 148 provides a templating layer having rough or textured features to assist in the nucleation of the materials of the conductor layer 150, e.g., the topological or anisotropic conductor. The conductor layer 150 can include any thickness; however, a thickness of 2 nm or less is preferred.

The process of forming templating layers and conductor layers can be repeated to provide a plurality of layers (multilayers) including topological or anisotropic conductors. In an embodiment, an additional topological or anisotropic conductor can be applied followed by a core layer (120, FIG. 3) or two or more layers of topological or anisotropic conductors can be employed. It is preferable to have each topological or anisotropic conductor have a thickness of less than 2 nm. In some embodiments, the vias formed can include circular shapes, polygonal shapes including square and rectangles, ovals, etc. In any case, the one or more insertion layers 118 follow a contour of the via hole and shape, with the exception of the core layer 120 which is located in a center of the shape.

Referring to FIG. 18, a free surface of the semiconductor device 100 can be planarized using e.g., CMP. The CMP process removes excess material of the conductor layer 150, the partition layer 148, the conductor layer 146 and the buffer layer 110 down to the dielectric layer 108. This forms the primary conductor 112 and the one or more insertion layers 118 of the via 126 (see also FIG. 2). Processing continues with the formation of metal line 104 (FIG. 2) by subtractive patterning of a plate to form metal lines or by forming damascene structure metal lines.

In other embodiments, contact interfaces 132 and 134 (FIG. 4-6) can be employed. If the contact interface 134 is employed, the contact interface 134 can be formed by a deposition process on the contact 102 prior to formation of the SAM layer 142. If contact interface 132 is employed, the contact interface can be formed after the via 106, 126, 136 is planarized. The contact interfaces 132 and 134 improve contact resistance between vias 106, 126, 136 and the metal line 104 and the contact 102, respectively.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a vertical interconnect having an enhanced conductor; and
a buffer layer disposed between the enhanced conductor and a dielectric material;
the enhanced conductor and the buffer layer including vertically disposed interfaces with surface-state conductive paths along the vertically disposed interfaces.

2. The semiconductor device of claim 1, wherein the buffer layer includes two-dimensional (2D) materials selected from the group consisting of graphene, mica, hexagonal boron nitride, transition metal dichalcogenides, MXenes, 2D native oxides and 2D selenides.

3. The semiconductor device of claim 1, wherein the enhanced conductor includes a topological conductor selected from the group consisting of triple point topological metal MoP, Weyl semimetal NbAs, multifold fermion semimetals CoSi and PdGa, quasi-2D type-II Weyl semimetal MoTe₂, topological Kagome metal CoSn, Dirac semimetal Cd₃As₂, and topological nodal line semimetal TiS and ZrSiS.

4. The semiconductor device of claim 1, wherein the enhanced conductor includes an anisotropic conductor selected from the group consisting of PtCoO₂, PdCoO₂, doped multilayer graphene, Fe₃GeTe₂, TaTMTe₄, NbTMTe₄, WTe₂, and MoTe₂, where TM is Ir, Rh or Ru.

5. The semiconductor device of claim 1, further comprising one or more insertion layers disposed within the enhanced conductor.

6. The semiconductor device of claim 5, wherein the one or more insertion layers include a dielectric material.

7. The semiconductor device of claim 5, wherein the one or more insertion layers include a semiconductor material.

8. The semiconductor device of claim 5, wherein the one or more insertion layers segment the enhanced conductor into portions having dimensions of 2 nm or less.

9. The semiconductor device of claim 1, wherein the vertical interconnect includes a via.

10. A semiconductor device, comprising:
an interconnect having an enhanced conductor; and
a buffer layer disposed between the enhanced conductor and a dielectric material;
one or more insertion layers disposed within the enhanced conductor. the one or more insertion layers and the buffer layer including interfaces with an enhanced conductor that have surface-state conductive paths along the interfaces wherein the one or more insertion layers partition the enhanced conductor into segments having dimensions of 2 nm or less.

11. The semiconductor device of claim 10, wherein the buffer layer includes two-dimensional (2D) materials selected from the group consisting of graphene, mica, hexagonal boron nitride, transition metal dichalcogenides, MXenes, 2D native oxides and 2D selenides.

12. The semiconductor device of claim 10, wherein the enhanced conductor includes a topological conductor selected from the group consisting of triple point topological metal MoP, Weyl semimetal NbAs, multifold fermion semimetals CoSi and PdGa, quasi-2D type-II Weyl semimetal MoTe₂, topological Kagome metal CoSn, Dirac semimetal Cd₃As₂, and topological nodal line semimetal TiS and ZrSiS.

13. The semiconductor device of claim 10, wherein the enhanced conductor includes an anisotropic conductor selected from the group consisting of PtCoO₂, PdCoO₂, doped multilayer graphene, Fe₃GeTe₂, TaTMTe₄, NbTMTe₄, WTe₂, and MoTe₂, where TM is Ir, Rh or Ru.

14. The semiconductor device of claim 10, further comprising a core layer within the enhanced conductor.

15. The semiconductor device of claim 10, wherein the one or more insertion layers include a dielectric material.

16. The semiconductor device of claim 10, wherein the one or more insertion layers include a semiconductor material.

17. The semiconductor device of claim 10, wherein the interconnect includes a via.

18. A method of fabricating an interconnect structure, comprising:
forming a self-assembled monolayer (SAM) on a contact exposed in an opening within a dielectric layer;
depositing a buffer layer on sidewalls of the opening where deposition of the buffer layer is inhibited on the contact due to the SAM layer;
removing the SAM layer;
depositing an enhanced conductor in the opening over the buffer layer; and
forming a conductive line in direct contact with the enhanced conductor wherein interfaces between the enhanced conductor and the buffer layer have surface-state conductive paths along the interfaces.

19. The method of claim 18, wherein the enhanced conductor includes a topological conductor or an anisotropic conductor.

20. The method of claim 18, further comprising depositing one or more insertion layers within the enhanced conductor to form segments in the enhanced conductor having dimensions of 2 nm or less.
